(19) United States
(12) Patent Application Publication
(10) Pub. No.: US 2025/0255085 A1
(43) Pub. Date: Aug. 7, 2025

(54) DETECTION DEVICE

(71) Applicant: Japan Display Inc., Tokyo (JP)

(72) Inventors: Kazuhide Mochizuki, Tokyo (JP); Keiichi Saito, Tokyo (JP); Isao Suzumura, Tokyo (JP); Yasushi Tomioka, Tokyo (JP); Gen Koide, Tokyo (JP)

(21) Appl. No.: 19/188,582

(22) Filed: Apr. 24, 2025

Related U.S. Application Data
(63) Continuation of application No. PCT/JP2023/037349, filed on Oct. 16, 2023.

(30) Foreign Application Priority Data
Oct. 26, 2022 (JP) 2022-171667

(51) Int. Cl. H10K 39/32; G06V 40/13; G06V 40/145

(52) U.S. Cl. CPC H10K 39/32; G06V 40/13; G06V 40/145

(57) ABSTRACT

According to an aspect, a detection device includes: a substrate; a plurality of photodiodes in which a lower electrode, a lower buffer layer, an active layer, an upper buffer layer, and an upper electrode are stacked on the substrate in the order as listed; and an insulating film provided between a plurality of the adjacent lower electrodes. The lower buffer layer includes an electrode-overlap portion that overlaps the lower electrode and an insulating-film overlap portion that overlaps at least a portion of the insulating film. A thickness of the insulating-film overlap portion of the lower buffer layer is smaller than a thickness of the electrode-overlap portion of the lower buffer layer.

### CROSS-REFERENCE TO RELATED APPLICATION

This application claims the benefit of priority from Japanese Patent Application No. 2022-171667 filed on Oct. 26, 2022 and International Patent Application No. PCT/JP2023/037349 filed on Oct. 16, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPD)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

When the buffer layer and the active layer are provided across a plurality of the photodiodes, or more specifically, when the buffer layer is provided across a plurality of the adjacent lower electrodes, leakage currents may occur between the adjacent lower electrodes.

### SUMMARY

According to an aspect, a detection device includes: a substrate; a plurality of photodiodes in which a lower electrode, a lower buffer layer, an active layer, an upper buffer layer, and an upper electrode are stacked on the substrate in the order as listed; and an insulating film provided between a plurality of the adjacent lower electrodes. The lower buffer layer includes an electrode-overlap portion that overlaps the lower electrode and an insulating-film overlap portion that overlaps at least a portion of the insulating film. A thickness of the insulating-film overlap portion of the lower buffer layer is smaller than a thickness of the electrode-overlap portion of the lower buffer layer.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a circuit diagram illustrating the detection device according to the first embodiment;

FIG. 4 is a magnified schematic configuration view of a sensor;

FIG. 5 is a sectional view along V-V′ of FIG. 4;

FIG. 6 is a plan view schematically illustrating an arrangement relation between a lower electrode and an insulating film;

FIG. 7 is a sectional view along VII-VII′ of FIG. 6;

FIG. 8 is a plan view schematically illustrating an arrangement relation between the lower electrode and the insulating film of a detection device according to a second embodiment;

FIG. 9 is a sectional view along IX-IX′ of FIG. 8;

FIG. 10 is a plan view schematically illustrating an arrangement relation between the lower electrode and an insulating film of a detection device according to a third embodiment;

FIG. 11 is a sectional view along XI-XI′ of FIG. 10;

FIG. 12 is a sectional view schematically illustrating a detection device according to a fourth embodiment; and

FIG. 13 is a sectional view schematically illustrating a detection device according to a modification of the fourth embodiment.

### DETAILED DESCRIPTION

The following describes modes (embodiments) for carrying out the present disclosure in detail with reference to the drawings. The present disclosure is not limited to the description of the embodiments to be given below. Components to be described below include those easily conceivable by those skilled in the art or those substantially identical thereto. In addition, the components to be described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate. In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

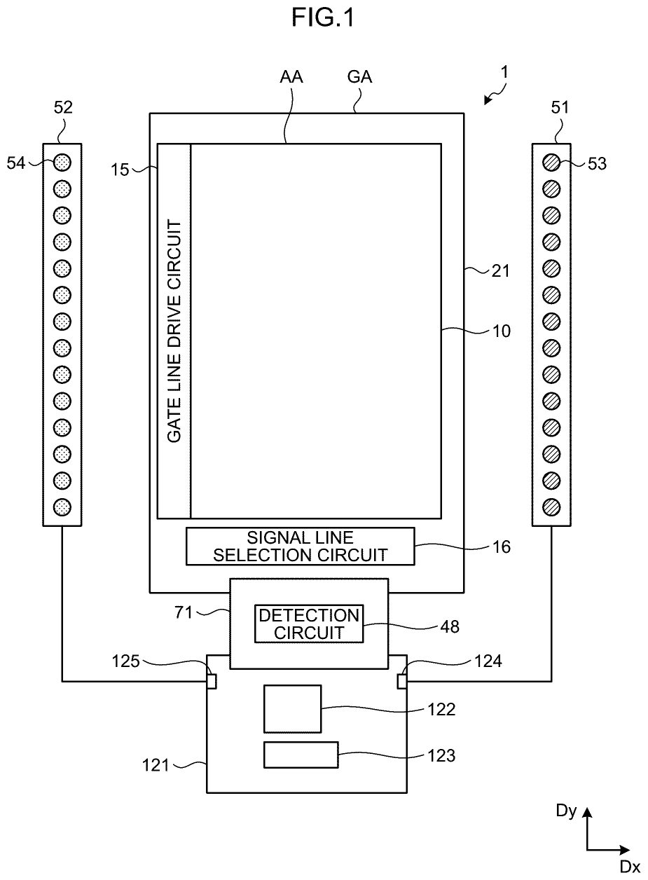

FIG. 1 is a plan view illustrating a detection device according to a first embodiment. As illustrated in FIG. 1, a detection device 1 includes a sensor base member 21 (substrate), a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

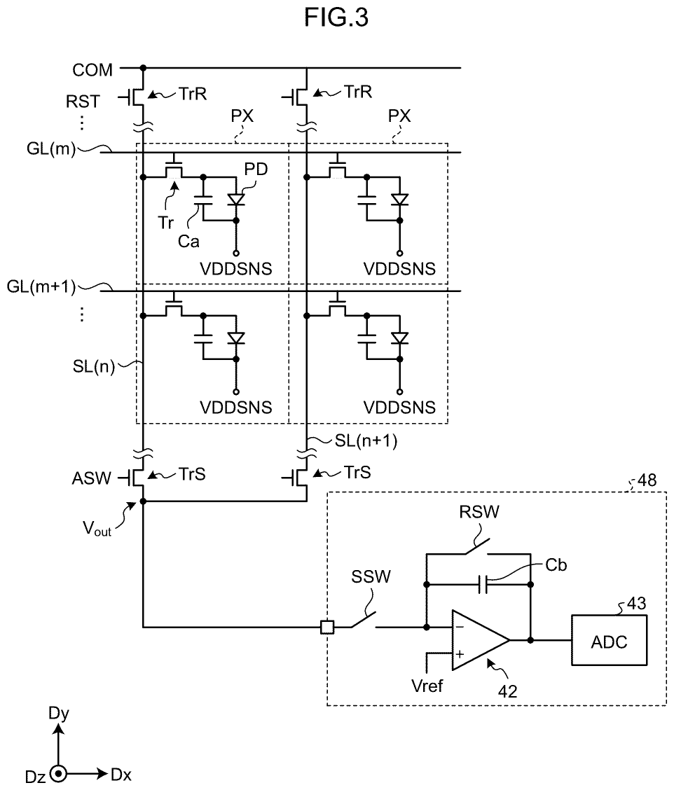

The sensor base member 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

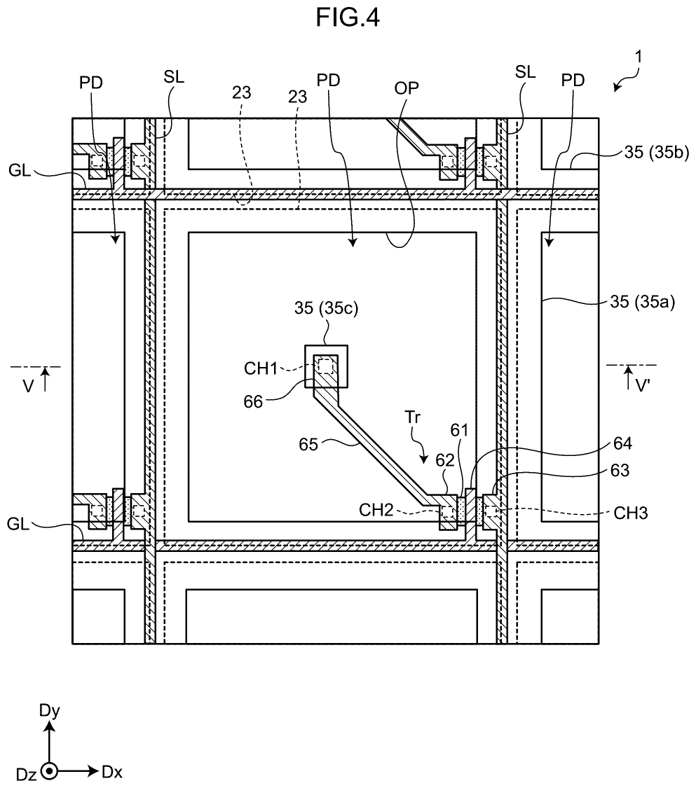

The sensor base member 21 has a detection region AA and a peripheral region GA. The detection region AA is a region provided with a plurality of photodiodes PD (refer to FIG. 4) included in the sensor 10. The peripheral region GA is a region between the outer perimeter of the detection region AA and the outer edges of the sensor base member 21 and is a region not provided with the photodiodes PD.

The gate line drive circuit 15 and the signal line selection circuit 16 are provided in the peripheral region GA. Specifically, the gate line drive circuit 15 is provided in a region extending along a second direction Dy in the peripheral region GA. The signal line selection circuit 16 is provided in a region extending along a first direction Dx in the peripheral region GA, and is provided between the sensor 10 and the detection circuit 48.

In the following description, a first direction Dx is one direction in a plane parallel to the sensor base member 21. The second direction Dy is one direction in the plane parallel to the sensor base member 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to a principal surface of the sensor base member 21. The term “plan view” refers to a positional relation when viewed from a direction orthogonal to the sensor base member 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect a fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

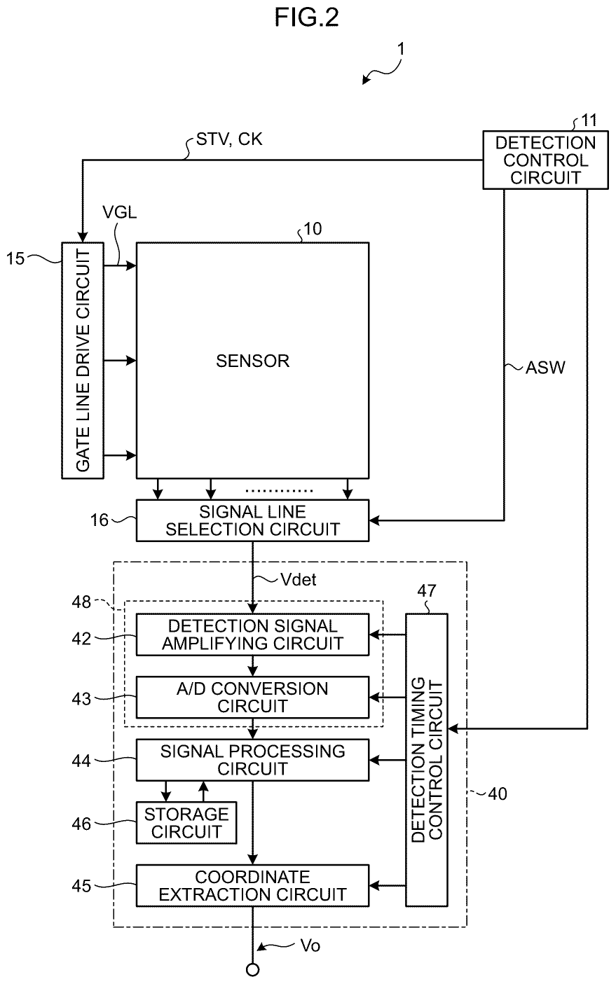

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light received by the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. By this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. By this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is a region surrounded by the gate lines GL and the signal lines SL.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The other of the sources and the drains of the drive transistors Tr are coupled to the anodes of the photodiodes PD and the capacitive elements Ca.

The cathode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 through an output transistor TrS of the signal line selection circuit 16. Thus, the detection device 1 can detect a signal corresponding to the amount of the light received by the photodiode PD for each sensor pixel PX.

During a readout period, a switch SSW is turned on to couple the detection circuit 48 to the signal line SL. The detection signal amplifying circuit 42 of the detection circuit 48 converts a current supplied from the signal line SL into a voltage corresponding to the value of the current and amplifies the result. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates, as each of the sensor output voltages Vo, the difference between the detection signal Vdet when the photodiode PD is irradiated with light and the detection signal Vdet when the photodiode PD is not irradiated with light. The detection signal amplifying circuit 42 includes a capacitive element Cb and a reset switch RSW. During a reset period, the reset switch RSW is turned on to reset the electric charge of the capacitive element Cb.

The drive transistor Tr is not limited to the n-channel TFT, and may be configured as a p-channel TFT. The pixel circuit of the sensor pixel PX illustrated in FIG. 3 is merely exemplary. The sensor pixel PX may be provided with a plurality of transistors corresponding to one photodiode PD.

The following describes a configuration of the photodiode PD. FIG. 4 is a magnified schematic configuration view of the sensor. As illustrated in FIG. 4, the detection device 1 includes the photodiodes PD provided on the sensor base member 21 and an insulating film 35. The gate lines GL each extend in the first direction Dx, and are arranged with gaps interposed therebetween in the second direction Dy. The signal lines SL each extend in the second direction Dy, and are arranged with gaps interposed therebetween in the first direction Dx. The photodiodes PD are each provided in a region surrounded by two of the gate lines GL and two of the signal lines SL and are provided in a matrix having a row-column configuration on the sensor base member 21.

A lower electrodes 23 of the photodiodes PD are provided in a matrix having a row-column configuration on the sensor base member 21 so as to correspond to the photodiodes PD. In the example illustrated in FIG. 4, the right and bottom sides of the lower electrode 23 overlap part of the signal line SL and part of the gate line GL, respectively. The left and top sides of the lower electrode 23 are located so as to be spaced from the signal line SL and the gate line GL, respectively. This configuration can increase the area (size) of the lower electrode 23 in the region surrounded by two of the gate lines GL and two of the signal lines SL, and thus can improve the detection sensitivity of the photodiode PD.

The drive transistor Tr is provided in a region overlapping the lower electrode 23 of the photodiode PD. Specifically, the drive transistor Tr includes a semiconductor layer 61, a source electrode 62, a drain electrode 63, and a gate electrode 64. The semiconductor layer 61 extends along the gate line GL and is provided so as to intersect the gate electrode 64 in plan view. The gate electrode 64 is coupled to the gate line GL and extends in a direction (second direction Dy) orthogonal to the gate line GL.

One end side of the semiconductor layer 61 is coupled to the source electrode 62 through a contact hole CH2. The source electrode 62 is coupled to coupling wiring 65 and a coupling pad 66 and drawn to a central portion of the photodiode PD (lower electrode 23). The lower electrode 23 is coupled to the coupling pad 66 through a contact hole CH1 at the central portion. Such a configuration electrically couples the source electrode 62 of the drive transistor Tr to the photodiode PD. The other end side of the semiconductor layer 61 is coupled to the drain electrode 63 through a contact hole CH3. The drain electrode 63 is coupled to the signal line SL.

The insulating film 35 is provided between the lower electrodes 23 adjacent in the first direction Dx and the second direction Dy, and is provided so as to cover the peripheries of the lower electrodes 23. In more detail, the insulating film 35 is formed in a grid pattern with first extending portions 35a and second extending portions 35b intersecting each other. Each of the first extending portions 35a extends in the second direction Dy. The first extending portion 35a is provided so as to overlap the signal line SL, and extends along the signal line SL. Each of the second extending portions 35b extends in the first direction Dx. The second extending portion 35b is provided so as to overlap the gate line GL and extends along the gate line GL.

In other words, openings OP are formed in the insulating film 35 in regions overlapping the respective lower electrodes 23. The opening OP is a region surrounded by two of the first extending portions 35a and two of the second extending portions 35b. An island 35c is provided so as to be separated from the first extending portions 35a and the second extending portions 35b and is provided in a region overlapping the contact hole CH1 in the central portion of the photodiode PD (lower electrode 23).

The shapes, the arrangement pitch, and the like of the lower electrodes 23 and the insulating film 35 illustrated in FIG. 4 are only exemplary and can be changed as appropriate according to the characteristics and the detection accuracy required for the detection device 1.

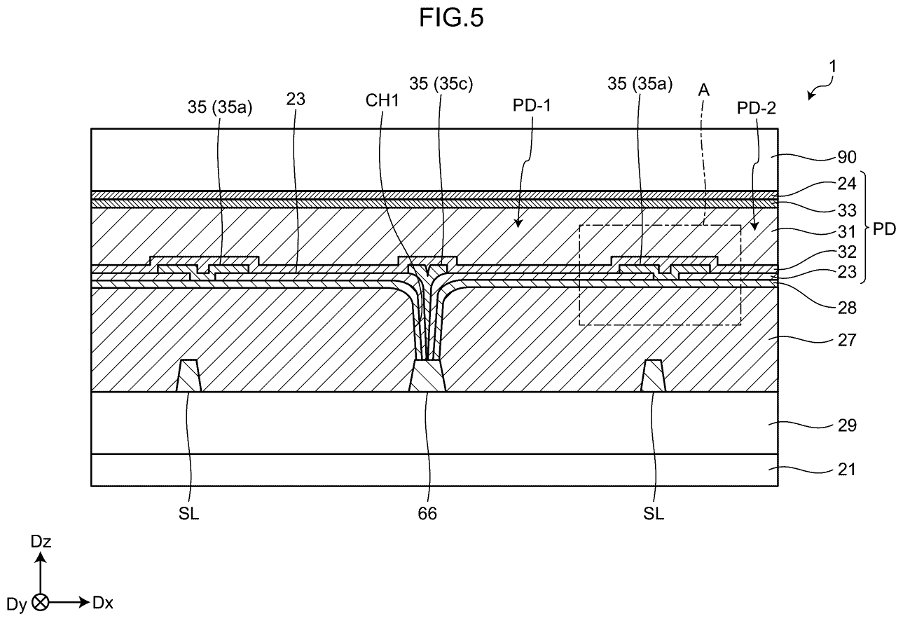

FIG. 5 is a sectional view along V-V′ of FIG. 4. As illustrated in FIG. 5, in the detection device 1, a circuit forming layer 29, an insulating film 27, the photodiode PD, and a sealing film 90 are stacked in this order on the sensor base member 21. The sensor base member 21 is an insulating substrate and is made using, for example, a glass substrate of quartz, alkali-free glass, or the like. The sensor base member 21 is not limited to having a flat plate shape but may have a curved surface. In this case, the sensor base member 21 may be made of a film-like resinous material.

The circuit forming layer 29 is a layer that is provided on the sensor base member 21, and on which various transistors, such as the drive transistors Tr illustrated in FIGS. 3 and 4, and various types of wiring, such as the gate lines GL and the signal lines SL, are formed. FIG. 5 illustrates the signal lines SL coupled to the drive transistors Tr. An insulating film 27 is provided on the circuit forming layer 29 including the drive transistors Tr so as to cover the signal lines SL. The insulating film 27 is an organic planarizing film formed of an organic insulating material.

An insulating film 28 is provided on the insulating film 27. The insulating film 28 is a barrier film formed of an inorganic insulating material, such as a silicon nitride (SiN) film.

The photodiode PD and the insulating film 35 are provided on the insulating film 28. In more detail, the photodiode PD includes the lower electrode 23, a lower buffer layer 32, an active layer 31, an upper buffer layer 33, and an upper electrode 24. In the photodiode PD, the lower electrode 23, the lower buffer layer 32 (hole transport layer), the active layer 31, the upper buffer layer 33 (electron transport layer), and the upper electrode 24 are stacked in this order in the direction orthogonal to the sensor base member 21. The photodiode PD of the present embodiment is an organic photodiode (OPD) made using an organic semiconductor as the active layer 31.

The lower electrode 23 is an anode electrode of the photodiode PD and is formed of, for example, a light-transmitting conductive material such as indium tin oxide (ITO). The lower electrodes 23 are separated from each other so as to correspond to the photodiodes PD. The lower buffer layer 32, the active layer 31, the upper buffer layer 33, and the upper electrode 24 are provided continuously across the photodiodes PD. Specifically, the lower buffer layer 32, the active layer 31, the upper buffer layer 33, and the upper electrode 24 are provided so as to overlap an adjacent pair of the lower electrode 23 of a photodiode PD-1 and the lower electrode 23 of a photodiode PD-2, and overlap also the insulating film 35 between the photodiodes PD-1 and PD-2.

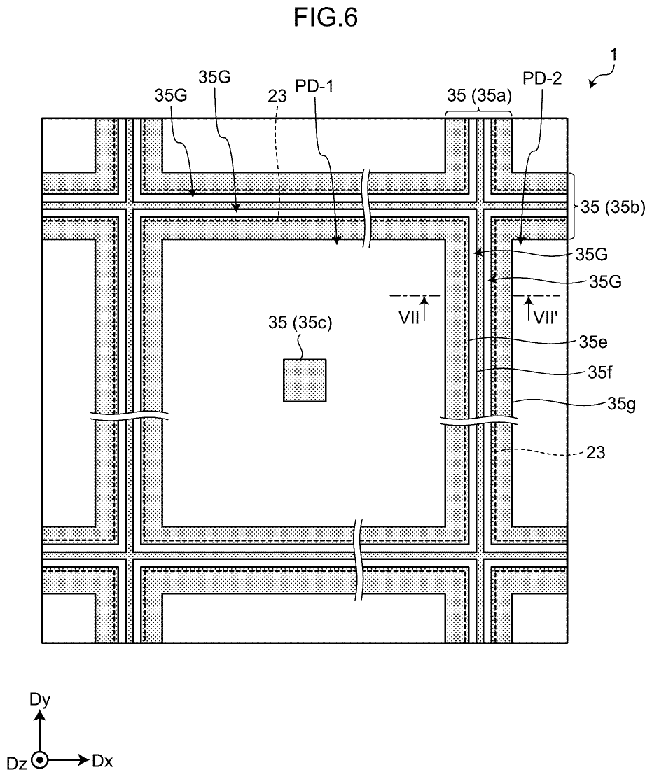

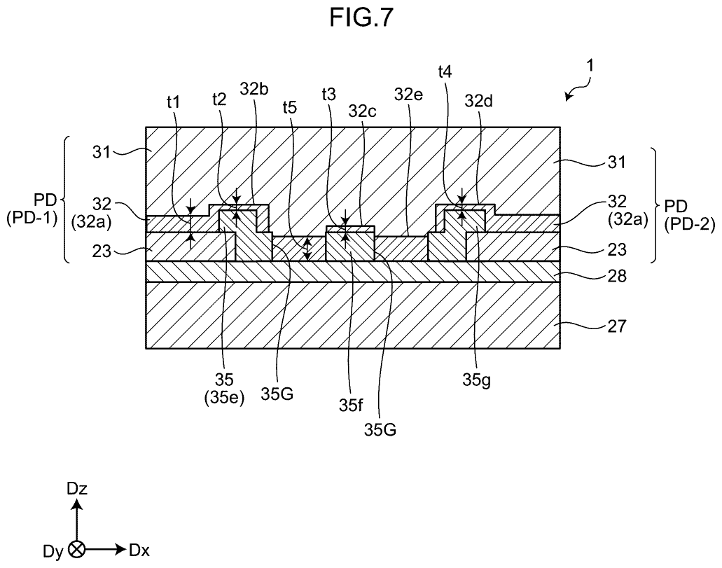

The insulating film 35 (first extending portion 35a) is provided on the insulating film 28 between the adjacent lower electrodes 23, and covers the peripheries of the lower electrodes 23. In the present embodiment, the insulating film 35 is formed of an inorganic insulating material, such as a silicon nitride (SiN) film or a silicon oxide (SiO₂) film. The insulating film 35 (first extending portion 35a) insulates the lower electrodes 23 of the adjacent photodiodes PD from each other. A detailed configuration of the insulating film 35 will be described later with reference to FIGS. 6 and 7.

The contact hole CH1 is provided so as to penetrate the insulating film 27 in the thickness direction thereof (third direction Dz) at the central portion of the lower electrode 23. The lower electrode 23 is coupled to the coupling pad 66 at the bottom of the contact hole CH1. The island 35c is provided so as to cover the contact hole CH1 and covers the lower electrode 23 in the contact hole CH1. The island 35c overlaps the coupling pad 66 in plan view. With this configuration, even if a step break occurs in the lower buffer layer 32 (hole transport layer) in the contact hole CH1, a short circuit between the active layer 31 and the lower electrode 23 can be restrained from occurring because the island 35c is provided.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-channel organic semiconductor and an n-channel fullerene derivative ((6,6)-phenyl-C61-butyric acid methyl ester (PCBM)) that is an n-channel organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer, and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 (hole transport layer) is in direct contact with the top of the lower electrode 23 and is also provided on the insulating film 35 between the adjacent lower electrodes 23. The active layer 31 is in direct contact with the top of the lower buffer layer 32. The material of the hole transport layer is a metal oxide layer. For example, tungsten oxide (WO₃) or molybdenum oxide is used as the oxide metal layer.

The upper buffer layer 33 (electron transport layer) is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, but may be formed as a multilayered film that includes an electron block layer and a hole block layer.

The upper electrode 24 is provided on the upper buffer layer 33. The upper electrode 24 is a cathode electrode of the photodiode PD and is continuously formed over the entire detection region AA. In other words, the upper electrode 24 is continuously provided at the top of the photodiodes PD. The upper electrode 24 faces the lower electrodes 23 with the lower buffer layer 32, the active layer 31, and the upper buffer layer 33 interposed therebetween. The upper electrode 24 is formed, for example, of a light-transmitting conductive material such as ITO or indium zinc oxide (IZO). The upper electrode 24 may be a multilayered film of a plurality of light-transmitting conductive materials.

The sealing film 90 is provided on the upper electrode 24. An inorganic film, such as a silicon nitride film, or an aluminum oxide film or a resin film, such as an acrylic film, is used as the sealing film 90. The sealing film 90 is not limited to a single layer and may be a multilayered film having two or more layers obtained by combining the inorganic film with the resin film mentioned above. The sealing film 90 well seals the photodiode PD, and thus can reduce moisture entering the photodiode PD from the upper surface side thereof.

The configuration of the photodiode PD illustrated in FIGS. 4 and 5 is merely exemplary and can be changed as appropriate. For example, the upper electrode 24 may be the anode electrode of the photodiode PD, and the lower electrode 23 may be the cathode electrode of the photodiode PD.

The following describes a detailed configuration of the insulating film 35, the lower electrode 23, and the lower buffer layer 32. FIG. 6 is a plan view schematically illustrating an arrangement relation between the lower electrode and the insulating film. FIG. 7 is a sectional view along VII-VII′ of FIG. 6. FIG. 6 illustrates the insulating film 35 with shading to facilitate viewing of the drawing. FIG. 7 is a sectional view illustrating a magnified view of a region A indicated by a long dashed short dashed line in FIG. 5.

As illustrated in FIG. 6, the insulating film 35 is provided in a grid pattern so as to cover the peripheries of the lower electrodes 23. The first extending portion 35a is provided between the lower electrodes 23 adjacent in the first direction Dx and extends in the second direction Dy along the sides of the lower electrodes 23. The second extending portion 35b is provided between the lower electrodes 23 adjacent in the second direction Dy and extends in the first direction Dx along the sides of the lower electrodes 23.

The insulating film 35 (first and second extending portions 35a and 35b) has a plurality of grooves 35G extending along the sides of the lower electrodes 23 between the adjacent lower electrodes 23. The grooves 35G are located between the adjacent lower electrodes 23 and provided so as to surround the lower electrodes 23 in plan view.

As illustrated in FIGS. 6 and 7, in the present embodiment, two grooves 35G are provided between the adjacent lower electrodes 23. The two grooves 35G extend along the extending direction of the first extending portion 35a and are provided adjacent to each other in the width direction of the first extending portion 35a. Similarly, the two grooves 35G extend along the extending direction of the second extending portion 35b and are provided adjacent to each other in the width direction of the second extending portion 35b. In other words, the insulating film 35 (first and second extending portions 35a and 35b) is separated into three parts by the two grooves 35G between the adjacent lower electrodes 23.

Specifically, in the photodiodes PD-1 and PD-2 adjacent in the first direction Dx, the insulating film 35 has electrode-side overlap portions 35e and 35g and a protruding portion 35f separated by the two grooves 35G. The electrode-side overlap portion 35e is provided so as to overlap a side of the lower electrode 23 of the photodiode PD-1 and extends along the side (right side in FIG. 6) of the lower electrode 23. The electrode-side overlap portion 35g is provided so as to overlap a side of the lower electrode 23 of the photodiode PD-2 and extends along the side (left side in FIG. 6) of the lower electrode 23. The protruding portion 35f is located between the two grooves 35G and extends along the electrode-side overlap portions 35e and 35g.

Each of the electrode-side overlap portions 35e and 35g overlaps the four sides of the lower electrode 23 and is formed in a frame shape surrounding the lower electrode 23. The protruding portion 35f is provided at a location between the lower electrodes 23 that does not overlap the lower electrodes 23. The protruding portion 35f is provided in a grid pattern so as to surround each of the lower electrodes 23 arranged in a matrix having a row-column configuration.

The width (width in the first direction Dx) of the protruding portion 35f is smaller than the width (width in the first direction Dx) of the grooves 35G and smaller than a gap between the adjacent lower electrodes 23. The thickness of the insulating film 35 (electrode-side overlap portions 35e and 35g and protruding portion 35f) provided between the adjacent lower electrodes 23 is, for example, 20 nm to 200 nm. The thickness of the lower electrode 23 is, for example, 20 nm to 100 nm.

As illustrated in FIG. 7, the lower buffer layer 32 covers at least portions of the lower electrode 23 of the photodiode PD-1, the lower electrode 23 of the photodiode PD-2, and the insulating film 35 that are adjacent in the first direction Dx, and is also provided in the two grooves 35G. More specifically, the lower buffer layer 32 includes electrode-overlap portions 32a that overlap the lower electrodes 23, insulating-film overlap portions 32b, 32c, and 32d that overlap at least portions of the insulating film 35, and groove-overlap portions 32e that are provided on the insulating film 28 in the grooves 35G.

Each of the electrode-overlap portions 32a is provided in a region (opening OP (refer to FIG. 4)) of the lower electrode 23 not provided with the insulating film 35. The insulating-film overlap portion 32b is provided on the electrode-side overlap portion 35e of the insulating film 35. The insulating-film overlap portion 32c is provided on the protruding portion 35f of the insulating film 35. The insulating-film overlap portion 32d is provided on the electrode-side overlap portion 35g of the insulating film 35.

In the present embodiment, the lower buffer layer 32 is formed so as to cover the lower electrodes 23 and the insulating film 35, for example, using a coating method. This configuration allows the lower buffer layer 32 to be easily accumulated in a recess formed by the grooves 35G, the protruding portion 35f, and the electrode-side overlap portions 35e and 35g, and in a recess formed by the lower electrode 23 and the electrode-side overlap portions 35e and 35g of the insulating film 35 (that is, a region overlapping the opening OP (refer to FIG. 4)). In contrast to this, the lower buffer layer 32 applied on the insulating film 35 is thinly formed by flowing from the top of the insulating film 35 toward the grooves 35G or the lower electrodes 23.

As a result, in the present embodiment, thicknesses t2, t3, and t4 of the insulating-film overlap portions 32b, 32c, and 32d of the lower buffer layer 32 are smaller than a thickness t1 of the electrode-overlap portion 32a of the lower buffer layer 32. The thicknesses t2, t3, and t4 of the insulating-film overlap portions 32b, 32c, and 32d of the lower buffer layer 32 are also smaller than a thickness t5 of the groove-overlap portions 32e of the lower buffer layer 32.

With this configuration, the insulating-film overlap portions 32b, 32c, and 32d of the lower buffer layer 32 located between the adjacent lower electrodes 23 have higher resistance values than the electrode-overlap portion 32a. As a result, the lower buffer layer 32 (insulating-film overlap portions 32b, 32c, and 32d) in regions overlapping the insulating film 35 serves as a potential barrier between the adjacent lower electrodes 23. Therefore, in the present embodiment, leakage currents flowing between the adjacent lower electrodes 23 can be reduced as compared with a case where the lower buffer layer 32 is continuously provided having a constant thickness over the adjacent photodiodes PD.

The lower buffer layer 32 provided on the insulating film 35 is broken stepwise by steps formed by the grooves 35G, the protruding portion 35f, and the like. Specifically, the lower buffer layer 32 (insulating-film overlap portion 32c) provided on the protruding portion 35f of the insulating film 35 is provided so as to be separated from the lower buffer layer 32 (groove-overlap portions 32e) provided in the grooves 35G. The lower buffer layer 32 (insulating-film overlap portions 32b and 32d) provided on the electrode-side overlap portion 35e of the insulating film 35 is provided so as to be separated from the lower buffer layer 32 (groove-overlap portions 32e) provided in the grooves 35G. As described above, the width (width in the first direction Dx) of the protruding portion 35f of the insulating film 35 is formed to be smaller than the width (width in the first direction Dx) of the grooves 35G. Therefore, a step break can be well generated between the insulating-film overlap portion 32c and the groove-overlap portions 32e.

As a result, in the adjacent photodiodes PD (for example, photodiodes PD-1 and PD-2), a separated non-contiguous portion is formed between the lower buffer layer 32 provided in the photodiode PD-1 and the lower buffer layer 32 provided in the photodiode PD-2. This configuration allows the detection device 1 to effectively reduce the leakage currents flowing between the adjacent lower electrodes 23.

Since the insulating film 35 forms the insulating-film overlap portions 32b, 32c, and 32d of the lower buffer layer 32 as high resistance regions, the gap between the lower electrodes 23 (or the width of the insulating film 35) can be made smaller than in a case where the electrode-overlap portion 32a of the lower buffer layer 32 and the insulating-film overlap portions 32b, 32c, and 32d are formed to have a constant thickness. This configuration can increase the effective region of the detection region AA of the detection device 1, and thus can improve the detection sensitivity. Alternatively, the region of the lower electrode 23 can be reduced, and the detection device 1 can achieve higher definition.

In the present embodiment, the gap between the lower electrodes 23 (or the width of the insulating film 35) can be reduced. Therefore, a delay in arrival time of carriers (holes and electrons) generated in the active layer 31 can be reduced between a portion of the photodiode PD overlapping the insulating film 35 and a portion of the photodiode PD not overlapping the insulating film 35.

The configuration of the insulating film 35 and the lower buffer layer 32 illustrated in FIGS. 6 and 7 is merely exemplary and can be changed as appropriate. For example, the insulating film 35 is provided with the two grooves 35G between the adjacent lower electrodes 23, but the number of the grooves 35G is not limited to two. One groove 35 or three or more grooves 35G may be provided between the adjacent lower electrodes 23. The insulating film 35 may be provided with no grooves 35G. Even in this case, at least the thicknesses t2 and t4 of the insulating-film overlap portions 32b and 32d of the lower buffer layer 32 are formed to be smaller than the thickness t1 of the electrode-overlap portion 32a of the lower buffer layer 32. Therefore, the detection device 1 can reduce the leakage current flowing between the adjacent lower electrodes 23 even if the insulating film 35 is not provided with the grooves 35G.

As illustrated in FIG. 6, the electrode-side overlap portions 35e and 35g of the insulating film 35 are each continuously provided so as to surround the lower electrode 23. The protruding portion 35f of the insulating film 35 is provided continuously across the lower electrodes 23. However, not limited to this configuration, the electrode-side overlap portions 35e and 35g and the protruding portion 35f may each be formed so as to be separated into a plurality of portions.

As illustrated in FIG. 7, the lower buffer layer 32 is provided so as to overlap each of the electrode-side overlap portions 35e and 35g and the protruding portion 35f of the insulating film 35. However, not limited to this configuration, the lower buffer layer 32 may be not provided in a portion of the insulating film 35. For example, the lower buffer layer 32 may be provided on the electrode-side overlap portions 35e and 35g of the insulating film 35 and not provided on the protruding portion 35f (that is, thickness t3=0 nm).

### Second Embodiment

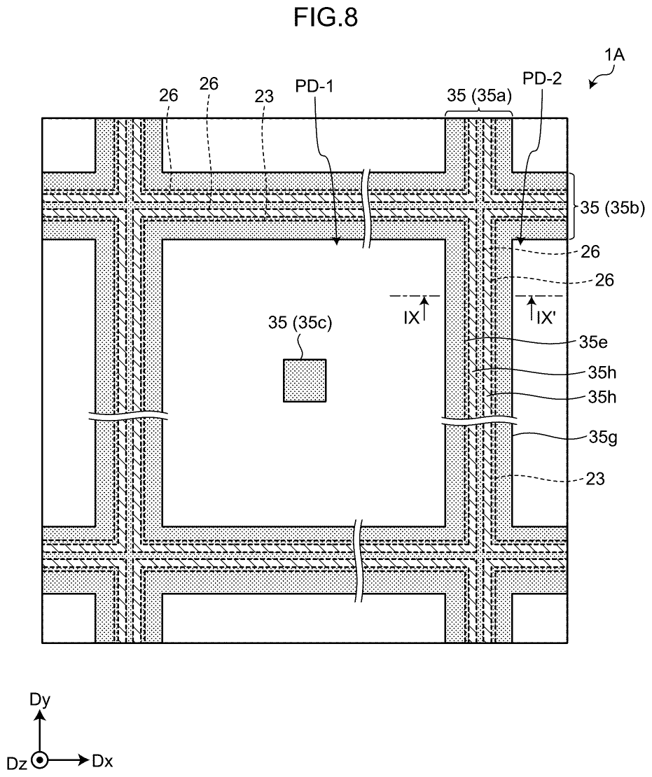

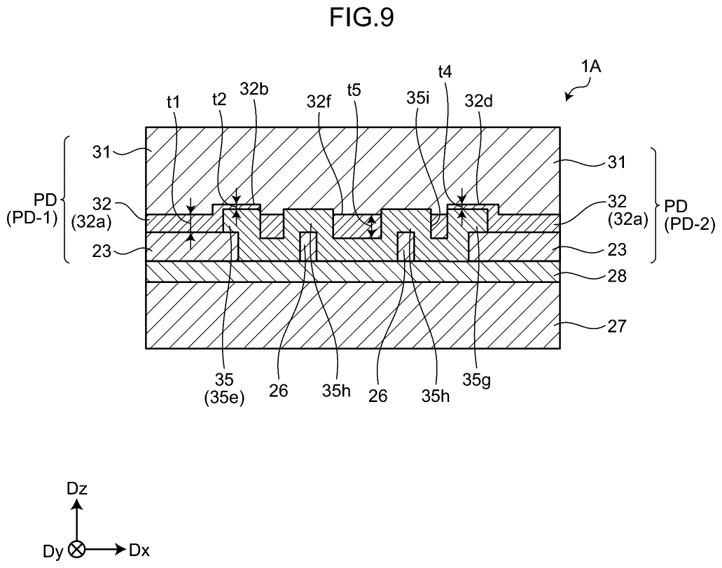

FIG. 8 is a plan view schematically illustrating an arrangement relation between the lower electrode and the insulating film of a detection device according to a second embodiment. FIG. 9 is a sectional view along IX-IX′ of FIG. 8. FIG. 8 illustrates the insulating film 35 and walls 26 with shading to facilitate viewing of the drawing. In the following description, the same components as those described in the embodiment above are denoted by the same reference numerals, and the description thereof will not be repeated.

As illustrated in FIG. 8, in a detection device 1A according to the second embodiment, the insulating film 35 is not provided with the grooves 35G and is provided continuously between the adjacent lower electrodes 23. The detection device 1A includes the walls 26 provided between the adjacent lower electrodes 23 so as to be separated from the lower electrodes 23. Each of the walls 26 is provided so as to extend along the sides of the lower electrode 23 and surround the lower electrode 23 in plan view. The wall 26 is provided so as to overlap the insulating film 35 and extends along the extending direction of the insulating film 35. In the example illustrated in FIG. 8, two walls 26 are provided between the adjacent lower electrodes 23.

As illustrated in FIG. 9, the two walls 26 are provided in the same layer as the lower electrodes 23 on the insulating film 28 and formed of the same material as the lower electrodes 23. The two walls 26 are formed of a light-transmitting conductive material such as ITO. The thickness of each of the walls 26 is, for example, 20 nm to 100 nm.

The insulating film 35 is provided between the adjacent lower electrodes 23 so as to cover the two walls 26. The insulating film 35 is provided along asperities formed by the lower electrodes 23 and the two walls 26 and is formed with the asperities. Specifically, in the photodiodes PD-1 and PD-2 adjacent in the first direction Dx, the insulating film 35 has the electrode-side overlap portions 35e and 35g and two protruding portions 35h.

The electrode-side overlap portion 35e is provided so as to overlap a side (right side in FIG. 8) of the lower electrode 23 of the photodiode PD-1 and extends along the side of the lower electrode 23. The electrode-side overlap portion 35g is provided so as to overlap the side (left side in FIG. 8) of the lower electrode 23 of the photodiode PD-2 and extends along the side of the lower electrode 23. The protruding portions 35h are provided so as to overlap the two respective walls 26 and extend along the electrode-side overlap portions 35e and 35g.

A recess 35i of the insulating film 35 is formed between the electrode-side overlap portion 35e and one of the protruding portions 35h of the insulating film 35, between the two adjacent protruding portions 35h, and between the other of the protruding portions 35h and the electrode-side overlap portion 35g.

The lower buffer layer 32 is provided so as to cover at least portions of the lower electrode 23 of the photodiode PD-1, the lower electrode 23 of the photodiode PD-2, and the insulating film 35 that are adjacent in the first direction Dx. More specifically, the lower buffer layer 32 includes the electrode-overlap portion 32a that overlaps the lower electrode 23, the insulating-film overlap portions 32b and 32d that overlap the electrode-side overlap portions 35e and 35g, respectively, of the insulating film 35, and a recess-overlap portion 32f provided in the recess 35i.

In FIG. 9, the lower buffer layer 32 is not provided on the two protruding portions 35h. However, the lower buffer layer 32 may be provided on the two protruding portions 35h in the same way as the insulating-film overlap portion 32c illustrated in FIG. 7.

Also in the present embodiment, the thicknesses t2 and t4 of the insulating-film overlap portions 32b and 32d of the lower buffer layer 32 are smaller than the thickness t1 of the electrode-overlap portion 32a of the lower buffer layer 32. The thicknesses t2 and t4 of the insulating-film overlap portions 32b and 32d of the lower buffer layer 32 are smaller than the thickness t5 of the recess-overlap portion 32f of the lower buffer layer 32.

Since the lower buffer layer 32 is not provided on the two protruding portions 35h of the insulating film 35, the recess-overlap portions 32f in the two recesses 35i are provided so as to be separated by the protruding portions 35h. In the same way as the insulating-film overlap portion 32c illustrated in FIG. 7, even if the lower buffer layer 32 is provided on the two protruding portions 35h, the lower buffer layer 32 on the protruding portions 35h and the recess-overlap portion 32f in the recess 35i are provided so as to be separated from each other. That is, the lower buffer layer 32 is broken stepwise by the protruding portions 35h and the recesses 35i.

With this configuration, also in the second embodiment, the insulating-film overlap portions 32b and 32d of the lower buffer layer 32 located between the adjacent lower electrodes 23 have higher resistance values than the electrode-overlap portion 32a. The lower buffer layer 32 provided on the insulating film 35 is broken stepwise by steps formed by the protruding portions 35h, the recesses 35i, and the like. Also in the present embodiment, this configuration can reduce the leakage current flowing between the adjacent lower electrodes 23.

### Third Embodiment

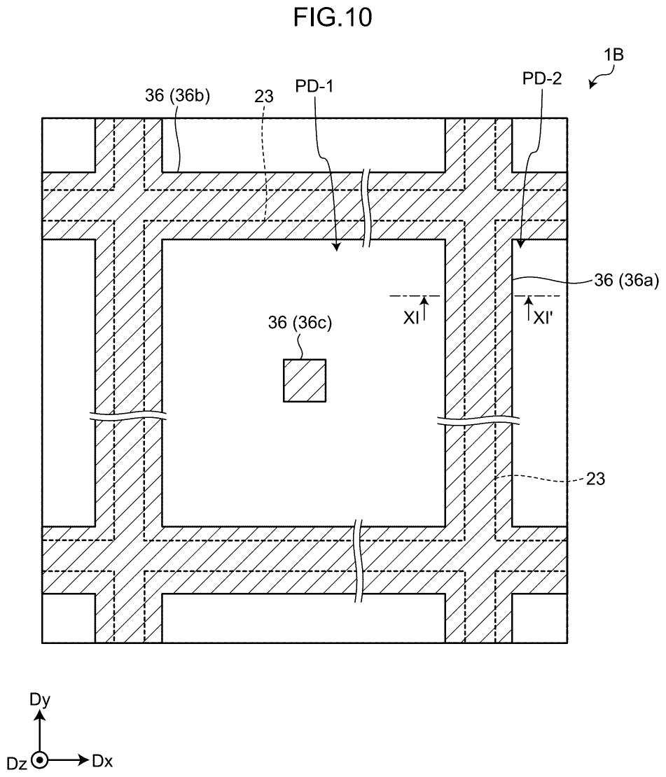

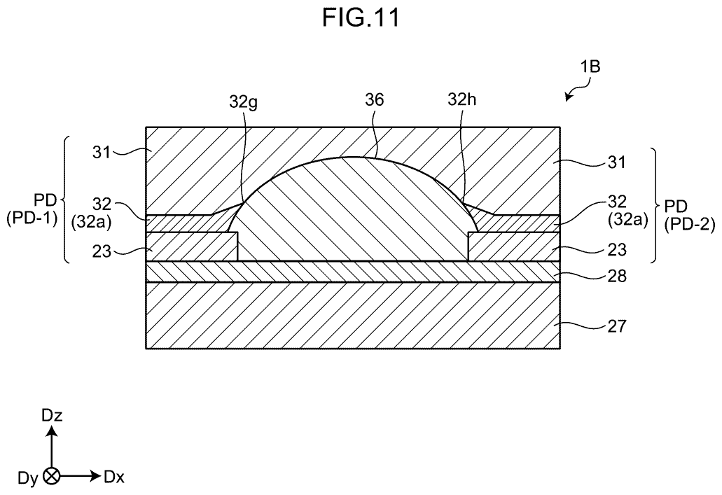

FIG. 10 is a plan view schematically illustrating an arrangement relation between the lower electrode and an insulating film of a detection device according to a third embodiment. FIG. 11 is a sectional view along XI-XI′ of FIG. 10.

As illustrated in FIGS. 10 and 11, a detection device 1B according to the third embodiment includes an organic insulating film 36 instead of the insulating film 35 formed of an inorganic insulating material. The organic insulating film 36 may, for example, be formed of the same organic insulating material as the insulating film 27. The organic insulating film 36 is provided between the lower electrodes 23 adjacent in the first direction Dx and the second direction Dy and covers the peripheries of the lower electrodes 23.

In more detail, the organic insulating film 36 is formed in a grid pattern with first extending portions 36a and second extending portions 36b intersecting each other. Each of the first extending portions 36a is provided between the lower electrodes 23 adjacent in the first direction Dx and extends in the second direction Dy along the sides of the lower electrodes 23. Each of the second extending portions 36b is provided between the lower electrodes 23 adjacent in the second direction Dy and extends in the first direction Dx along the sides of the lower electrodes 23.

The organic insulating film 36 includes an island 36c provided so as to be separated from the first extending portion 36a and the second extending portion 36b. The island 36c is provided in a region overlapping the contact hole CH1 (refer to FIG. 5) in the central portion of the photodiode PD (lower electrode 23). The island 36c is not limited to an organic insulating film and may be formed of an inorganic insulating film.

As illustrated in FIG. 11, the height (thickness) of the organic insulating film 36 is higher than the height (thickness) of the insulating film 35 formed of the inorganic insulating material described above. Thus, the lower buffer layers 32 of the adjacent photodiodes PD-1 and PD-2 are separated with the organic insulating film 36 interposed therebetween. More specifically, an outer edge 32g of the lower buffer layer 32 of the photodiode PD-1 is located so as to overlap a sloped surface of the organic insulating film 36. An outer edge 32h of the lower buffer layer 32 of the photodiode PD-2 is located so as to overlap a sloped surface of the organic insulating film 36 on the opposite side to the outer edge 32g. The lower buffer layer 32 is not provided at least at the top of the organic insulating film 36. In other words, the lower buffer layer 32 is provided in a region surrounded by the first extending portions 36a and the second extending portions 36b of the organic insulating film 36.

With this configuration, in the third embodiment, the lower buffer layer 32 is provided so as to be separated for each of the photodiodes PD (lower electrode 23) by the organic insulating film 36. Also in the present embodiment, this configuration can reduce the leakage current flowing between the adjacent lower electrodes 23, compared with a case where the lower buffer layer 32 is provided continuously across the adjacent photodiode PD.

### Fourth Embodiment

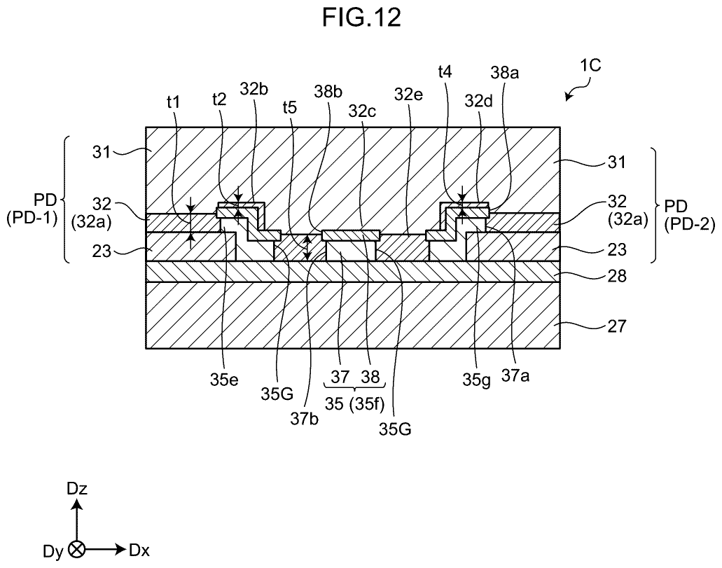

FIG. 12 is a sectional view schematically illustrating a detection device according to a fourth embodiment. As illustrated in FIG. 12, in a detection device 1C of the fourth embodiment, the insulating film 35 is a multilayered film in which a first insulating film 37 and a second insulating film 38 are stacked. The second insulating film 38 is stacked on top of the first insulating film 37. The first insulating film 37 is formed of a silicon oxide film, for example, and the second insulating film 38 is formed of a material, such as a silicon nitride film, different from the first insulating film 37.

The grooves 35G penetrating the first and the second insulating films 37 and 38 in the thickness direction (third direction Dz) are formed in the insulating film 35. The configuration of the insulating film 35 and the grooves 35G in plan view is the same as in the first embodiment described above (refer to FIG. 6), and will not be described again.

In the present embodiment, ends of the insulating film 35 (ends in the first direction Dx of the electrode-side overlap portions 35e and 35g that overlap the ends of the lower electrodes 23) each have a reverse-tapered shape. In more detail, an end 38a of the second insulating film 38 is provided so as to protrude in the first direction Dx more than an end 37a of the first insulating film 37. The end 38a of the second insulating film 38 is provided in a canopy-like manner with respect to the end 37a of the first insulating film 37.

Inner walls of the grooves 35G each also have a reverse-tapered shape. In each of the grooves 35G, an end 38b of the second insulating film 38 is provided so as to protrude more than an end 37b of the first insulating film 37. In other words, in the groove 35G, the distance between inner walls of the second insulating film 38 facing each other in the first direction Dx is smaller than the distance between inner walls of the first insulating film 37 facing each other in the first direction Dx.

The first and the second insulating films 37 and 38 are patterned by photolithography and etching processes. The reverse-tapered shape of the insulating film 35 can be formed using a difference in etching rate between the first and the second insulating films 37 and 38 when patterning the first and the second insulating films 37 and 38. For example, in the example illustrated in FIG. 12, the etching rate of the first insulating film 37 is higher than that of the second insulating film 38.

In the present embodiment, a space surrounded by the end 38a of the second insulating film 38 protruding in a canopy-like manner, the end 37a of the first insulating film 37, and the lower electrode 23 is formed at each of the ends of the insulating film 35 (electrode-side overlap portions 35e and 35g). The electrode-overlap portion 32a of the lower buffer layer 32 is provided so as to penetrate also into the space surrounded by the end 37a of the first insulating film 37, the end 38a of the second insulating film 38, and the lower electrode 23. This configuration facilitates a step break between the electrode-overlap portions 32a and 32b of the lower buffer layer 32.

A space surrounded by the end 38b of the second insulating film 38, the end 37b of the first insulating film 37, and the insulating film 28 is formed in the groove 35G. The groove-overlap portions 32e of the lower buffer layer 32 are provided also in the space surrounded by the end 38b of the second insulating film 38, the end 37b of the first insulating film 37, and the insulating film 28.

This configuration forms the space of the groove 35G larger than the groove 35G formed into a straight shape and not formed into a reverse-tapered shape (refer to FIG. 7). As a result, a step break can more easily occur between the groove-overlap portions 32e and the insulating-film overlap portion 32b of the lower buffer layers 32. Also in the present embodiment, the thicknesses t2 and t4 of the insulating-film overlap portions 32b and 32d of the lower buffer layer 32 are smaller than the thickness t1 of the electrode-overlap portion 32a of the lower buffer layer 32. The thicknesses t2 and t4 of the insulating-film overlap portions 32b and 32d of the lower buffer layer 32 are also smaller than the thickness t5 of the groove-overlap portions 32e of the lower buffer layer 32.

In the present embodiment, the lower buffer layer 32 is not provided on the second insulating film 38 of the protruding portion 35f. However, the lower buffer layer 32 may be provided on the second insulating film 38 of the protruding portion 35f in the same way as the insulating-film overlap portion 32c illustrated in FIG. 7. Even in this case, since the groove 35G is formed into the reverse-tapered shape, the lower buffer layer 32 provided on the protruding portion 35f and the groove-overlap portions 32e of the groove 35G are provided so as to be separated from each other. That is, the lower buffer layer 32 is broken stepwise by the protruding portion 35f and the grooves 35G.

### Modification

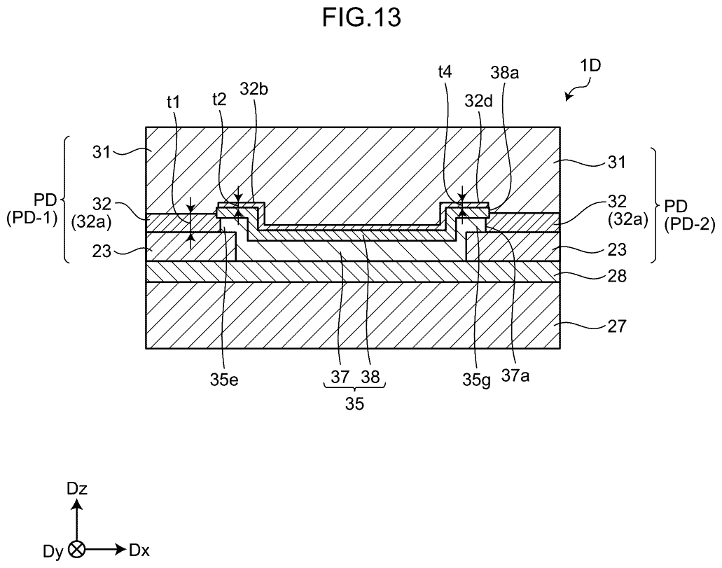

FIG. 13 is a sectional view schematically illustrating a detection device according to a modification of the fourth embodiment. As illustrated in FIG. 13, a detection device 1D according to the modification of the fourth embodiment differs from the detection device 1C (refer to FIG. 12) according to the fourth embodiment described above in that the detection device 1D is provided with no grooves 35G.

As illustrated in FIG. 13, in the detection device 1D according to the modification of the fourth embodiment, the insulating film 35 (first and second insulating films 37 and 38) is provided continuously between the adjacent lower electrodes 23. The ends of the insulating film 35 (electrode-side overlap portions 35e and 35g) are each formed into a reverse-tapered shape. In more detail, the end 38a of the second insulating film 38 protrudes in the first direction Dx more than the end 37a of the first insulating film 37 and is formed into the reverse-tapered shape.

As a result, at least the electrode-overlap portion 32a of the lower buffer layer 32 and the insulating-film overlap portions 32b and 32d become subject to a step break and are provided so as to be separated from each other. Also in the modification, the thicknesses t2 and t4 of the insulating-film overlap portions 32b and 32d of the lower buffer layer 32 are smaller than the thickness t1 of the electrode-overlap portion 32a of the lower buffer layer 32. Therefore, even in the configuration in which no grooves 35G are provided in the modification, the leakage current flowing between the adjacent lower electrodes 23 can be reduced.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modification described above.

What is claimed is:

1. A detection device comprising:
a substrate;
a plurality of photodiodes in which a lower electrode, a lower buffer layer, an active layer, an upper buffer layer, and an upper electrode are stacked on the substrate in the order as listed; and
an insulating film provided between a plurality of the adjacent lower electrodes, wherein
the lower buffer layer comprises an electrode-overlap portion that overlaps the lower electrode and an insulating-film overlap portion that overlaps at least a portion of the insulating film, and
a thickness of the insulating-film overlap portion of the lower buffer layer is smaller than a thickness of the electrode-overlap portion of the lower buffer layer.

2. The detection device according to claim 1, wherein the insulating film has a groove that is provided between the adjacent lower electrodes and extends along sides of the lower electrodes.

3. The detection device according to claim 1, wherein
the insulating film has
a plurality of grooves that are provided between the adjacent lower electrodes and extend along sides of the lower electrodes and
a protruding portion located between the grooves, and
the lower buffer layer provided on the protruding portion is provided so as to be separated from the lower buffer layer provided in each of the grooves.

4. The detection device according to claim 1, comprising a wall that is provided between the adjacent lower electrodes so as to be separated from the lower electrodes and is formed of the same material as the lower electrodes, wherein
the insulating film is provided between the adjacent lower electrodes so as to cover the wall.

5. The detection device according to claim 1, wherein the insulating film is formed of an organic insulating material.

6. The detection device according to claim 5, wherein the lower buffer layers of the adjacent photodiodes are separated from each other with the organic insulating film interposed between the lower buffer layers.

7. The detection device according to claim 1, wherein an end of the insulating film has a reverse-tapered shape.

8. The detection device according to claim 1, wherein
the insulating film comprises a first insulating film and a second insulating film provided on the first insulating film, and
an end of the second insulating film is provided so as to protrude more than an end of the first insulating film.

9. The detection device according to claim 8, wherein
the first insulating film is a silicon oxide film, and
the second insulating film is a silicon nitride film.

10. The detection device according to claim 3, wherein a thickness of the insulating-film overlap portion of the lower buffer layer is smaller than a thickness of the lower buffer layer provided in the grooves.

11. The detection device according to claim 1, wherein a thickness of the insulating film provided between the adjacent lower electrodes is 20 nm to 200 nm.

12. The detection device according to claim 4, wherein a thickness of the wall is 20 nm to 100 nm.

13. The detection device according to claim 3, wherein a width of the protruding portion is smaller than a width of the grooves and smaller than a gap between the adjacent lower electrodes.

14. The detection device according to claim 1, wherein the photodiodes are organic photodiodes (OPDs).
